(19) United States
(12) Patent Application Publication
(10) Pub. No.: US 2023/0315924 A1
(43) Pub. Date: Oct. 5, 2023

(54) SYSTEMS AND METHODS FOR MATERIALS DISCOVERY USING DUALITY TRANSFORMS AND PREDICTIVE CONVEX HULLS

(71) Applicant: Toyota Research Institute, Inc., Los Altos, CA (US)

(72) Inventors: Jens Strabo Hummelshøj, Brisbane, CA (US); Santosh K. Suram, Mountain View, CA (US)

(21) Appl. No.: 17/707,053

(22) Filed: Mar. 29, 2022

(51) Int. Cl. G06F 30/10; G06F 30/27; G06K 9/62

(52) U.S. Cl. CPC G06F 30/10; G06F 30/27; G06K 9/6256

(57) ABSTRACT

A system for material discovery includes a processor and a memory communicably coupled to the processor. The memory stores an acquisition module, a machine learning module, a duality transform module, and a convex hull module that include instructions that when executed by the processor cause the processor to select a dataset, train a machine learning model to learn a convex function approximating the dataset in a primal space, duality transform hyperplanes of the learned convex function from the primal space to a dual space, learn a convex hull of the duality transformed convex function hyperplanes in the dual space, duality transform at least one hyperplane of the learned convex hull back to the primal space, and predict, based on the at least one duality transformed hyperplane of the learned convex hull, at least one stable material composition within the material space.

### TECHNICAL FIELD

The present disclosure relates generally to materials discovery, and particularly to using machine learning for material discovery.

### BACKGROUND

The discovery of new materials and/or unknown properties of existing materials is desirable for continued technological developments in industries such as automotive, aerospace, energy production, chemical processing, and semiconductor manufacturing, among others. Also, the desire for such discoveries has fueled first-principle computational research in an effort to reduce the time and cost associated with materials development. And while first-principle computational research has led to the development of new alloys and semiconductors, computation time needed first-principle calculations can be longer than desired and/or not practical.

The present disclosure addresses issues related to computational discovery of new materials, and other issues related to material discovery.

### SUMMARY

This section provides a general summary of the disclosure, and is not a comprehensive disclosure of its full scope or all of its features.

In one form of the present disclosure, a system includes a processor and a memory communicably coupled to the processor. The memory stores machine-readable instructions that, when executed by the processor, cause the processor to select a dataset representing at least a portion of a material space and train a machine learning model to learn a convex function approximating the dataset in a primal space. In some variations, the machine-readable instructions, when executed by the processor, cause the processor to duality transform hyperplanes of the learned convex function from the primal space to a dual space, learn a convex hull of the duality transformed convex function hyperplanes in the dual space, and duality transform at least one hyperplane of the learned convex hull back to the primal space. And in at least one variation, the machine-readable instructions, when executed by the processor, cause the processor to predict, based on the at least one duality transformed hyperplane of the learned convex hull, at least one optimized material composition within the material space.

In another form of the present disclosure, a system includes a processor and a memory communicably coupled to the processor. The memory stores machine-readable instructions that, when executed by the processor, cause the processor to select a dataset representing at least a portion of a material space, train a machine learning model to learn a convex function approximating the dataset in a first space, learn a first minimum of learned convex function in the first space, transform a subspace of the learned convex function from the first space to a second space, the learned minimum in the first space being an endpoint in the second space, learn a second minimum of the subspace of the learned convex function in the second space. And in at least one variation, the machine-readable instructions, when executed by the processor, cause the processor to predict, based on the first learned minimum and the second learned minimum, a first optimized material composition and a second optimized material composition different than the first optimized material composition within the material space.

In still another form of the present disclosure, a method includes selecting a dataset from a candidate dataset representing at least a portion of a material space, training a machine learning model to learn a convex function approximating the dataset in a primal space, and duality transforming hyperplanes of the learned convex function from the primal space to a dual space. In some variations, the method also includes learning a convex hull of the duality transformed convex function hyperplanes in the dual space and duality transforming at least one hyperplane of the learned convex hull back to the primal space. And in at least one variation, the method includes predicting, based on the at least one duality transformed hyperplane of the learned convex hull, at least one optimized material composition within the material space.

Further areas of applicability and various methods of enhancing the above technology will become apparent from the description provided herein. The description and specific examples in this summary are intended for purposes of illustration only and are not intended to limit the scope of the present disclosure.

### BRIEF DESCRIPTION OF THE DRAWINGS

The present teachings will become more fully understood from the detailed description and the accompanying drawings, wherein:

FIG. 1 is a block diagram that illustrates an example of a machine learning system for predicting a new stable material composition according to the teachings of the present disclosure;

FIG. 2A shows a learned convex function ‘cf1’ for a plot of a formation energy versus composition dataset for a hypothetical A-B material system according to the teachings of the present disclosure;

FIG. 2B shows a learned minimum of the convex function cf1 in FIG. 1A with the minimum predicting a stable single-phase AB2 in the A-B material system according to the teachings of the present disclosure;

FIG. 2C shows a plot of the A-AB2 subspace in FIG. 1B, a learned convex function ‘cf2’ of the A-AB2 subspace, and a learned minimum of the convex function cf2 predicting a stable single-phase ASB in the A-B material system according to the teachings of the present disclosure;

FIG. 2D shows a plot of the A7B-AB2 subspace in FIG. 1C, a learned convex function ‘cf3’ of the A7B-AB2 subspace, and a learned minimum of the convex function cf3 predicting a stable single-phase A3B2 in the A-B material system according to the teachings of the present disclosure;

FIG. 3A is a plurality of hyperplanes of a learned convex function ‘cf4’ that approximates formation energy versus composition for one of the subspaces in FIGS. 1C-1D according to the teachings of the present disclosure;

FIG. 3B shows a duality transform of the hyperplanes in FIG. 3A to a dual space according to the teachings of the present disclosure;

FIG. 4 is a flow chart for a machine learning method using the system illustrated in FIG. 2 to predict a new stable material composition according to the teachings of the present disclosure;

FIG. 5 is a flow chart for another machine learning method using the system illustrated in FIG. 2 to predict a new stable material composition according to the teachings of the present disclosure; and

FIG. 6 is a flow chart for still another machine learning method using the system illustrated in FIG. 2 to predict a new stable material composition according to the teachings of the present disclosure.

### DETAILED DESCRIPTION

The present disclosure provides a machine learning (ML) system and a ML method for predicting an optimized material composition with respect to one or more material properties. As used herein, the phrase “optimized material composition” refers to a previously unknown stable single-phase material composition or a known stable single-phase material composition with a previously unknown crystal structure. Also, the term “stable” refers to a single-phase compound or crystal structure of a single-phase compound that does not change when the single-phase compound is being used as a functional material (i.e., while being used for its intended purpose). In one form of the present disclosure, the ML system and ML method train a ML model to learn a convex function of a data set, find a minimum of the learned convex function, and a minimum of any protrusions of the learned convex function such that one or more optimized material compositions is/are predicted. In another form of the present disclosure, the ML system and ML method train a ML model to learn a convex function of a data set, duality transform a plurality of hyperplanes of the convex function to a dual space, learn a convex hull of the duality transformed convex function hyperplanes, and then duality transform at least a portion of a plurality of hyperplanes of the convex hull back to the original space such that one or more optimized material compositions is/are predicted. As used herein, the term “hyperplane” as used herein refers to a subspace whose dimension is one less than the dimension of the ambient or primal space.

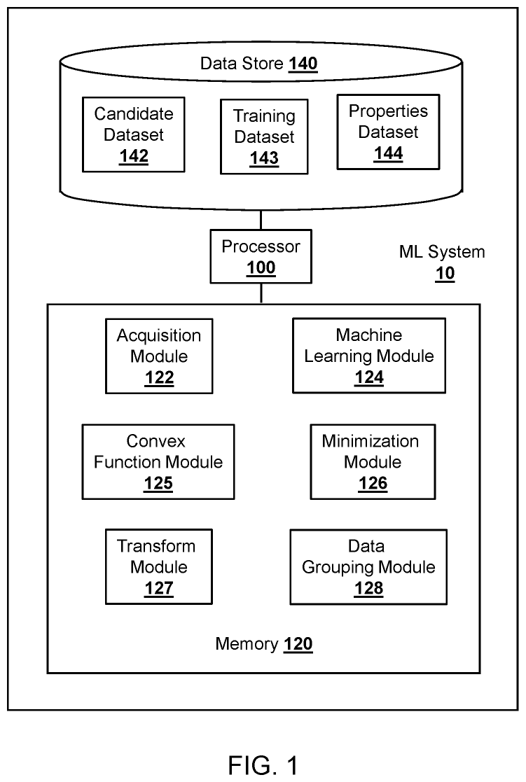

Referring now to FIG. 1, a ML system 10 for predicting an optimized material composition in a given or selected material system is illustrated. The ML system 10 is shown including one or more processor 100 (referred to herein simply as “processor 100”), a memory 120 and a data store 140 communicably coupled to the processor 100. It should be understood that the processor 100 can be part of the ML system 10, or in the alternative, the ML system 10 can access the processor 100 through a data bus or another communication path.

The memory 120 is configured to store an acquisition module 122 and a ML module 124. In some variations, the memory 120 is configured to also store a convex function module 125, a minimization module 126, a transform module 127 and/or a data grouping module 128. The memory 120 is a random-access memory (RAM), read-only memory (ROM), a hard-disk drive, a flash memory, or other suitable memory for storing the acquisition module 122 and the ML module 124, and for storing the convex function module 125, the minimization module 126, the transform module 127 and/or the data grouping module 128. Also, the acquisition module 122, ML module 124, convex function module 125, minimization module 126, transform module 127, and data grouping module 128 (collectively referred to herein as “modules 122-128”) are, for example, computer-readable instructions that when executed by the processor 100 cause the processor(s) to perform the various functions disclosed herein.

In some variations the data store 140 is a database, e.g., an electronic data structure stored in the memory 120 or another data store. Also, in at least one variation the data store 140 in the form of a database is configured with routines that can be executed by the processor 100 for analyzing stored data, providing stored data, organizing stored data, and the like. Accordingly, in some variations the data store 140 stores data used by one or more of the modules 122-128. For example, and as shown in FIG. 1, in at least one variation the data store stores a candidate material dataset 142 (also referred to herein simply as “candidate dataset 142”), a training dataset 143, and a material properties dataset 144. In some variations the candidate dataset 142 includes a listing of a plurality of material compositions, the training dataset 143 includes training data, sometimes referred to as “ground-truth data” in the form of training material compositions and known material property values for corresponding training material compositions, and the material properties dataset 144 includes material compositions with material property values, simulated and/or experimentally determined, from different material property datasets.

Material systems that can be in the candidate dataset 142 include metallic and ceramic systems for which material discovery is desired. For example, and without limitation, material systems in the candidate dataset 142 include materials such as alloys, intermetallics, semiconductors, semimetals, and dielectrics, among others. Material properties that can be in the properties dataset 144 include any property that is experimentally known and/or can be calculated for a materials system in the candidate dataset 142. For example, and without limitation, material properties in the properties dataset 144 include formation energy, electronic bandgap, electrical conductivity, thermal conductivity, acoustical absorption, acoustoelastic effect, surface energy, surface tension, capacitance, dielectric constant, dielectric strength, thermoelectric effect, permittivity, piezoelectricity, pyroelectricity, Seebeck coefficient, curie temperature, diamagnetism, hall coefficient, magnetic hysteresis, electrical hysteresis, magnetoresistance, maximum energy product, permeability, piezomagnetism, Young's modulus, viscosity, Poisson's ratio and density, among others.

The acquisition module 122 can include instructions that function to control the processor 100 to select a dataset including a plurality of material compositions from a predefined material system (e.g., the A-B material system) from the candidate dataset 142 and corresponding material property values for at least one predefined material property from the properties dataset 144. It should be understood that the material property values in the properties dataset 144 are properly tagged and/or associated with the plurality of material compositions in the candidate dataset 142. In some variations, acquisition module 122 includes instructions that function to control the processor 100 to select the dataset from the training dataset 143.

In one form of the present disclosure, the ML module 124, convex function module 125, minimization module 126, and the transform module 127 can include instructions that function to control the processor 100 to perform or execute one or more of the following: select a convex function from the convex function module 125; train the selected convex function to approximate (fit) at least a portion of the dataset in a first or primal space; select a minimization function from the minimization module 126; learn a minimum of the trained convex function in the first space using the minimization function; select a transform function from the transform module 127; transform a subspace of the trained convex function to a second or dual space using the transform function; learn a minimum of the transformed subspace in the second space; and predict one or more stable material compositions, based at least in part, on the learned minimums in the first space and the second space.

In another form of the present disclosure, the ML module 124, convex function module 125, minimization module 126, the transform module 127 and/or data grouping module 128 can include instructions that function to control the processor 100 to perform or execute one or more of the following: select a convex function from the convex function module 125; train the selected convex function to approximate (fit) at least a portion of the dataset; select a duality transform function from the transform module 127; duality transform one or more hyperplanes of the trained convex function from a primal space to a dual space using the transform module 127; select a grouping function from the data grouping module 128; train the grouping function such that a plurality of hyperplanes of the grouping function bound the duality transformed hyperplanes of the trained convex function; and duality transform at least one of the hyperplanes of the grouping function back to the primal space; and predict one or more optimized material compositions, based at least in part, on the and duality transform of at least one of the hyperplanes of the grouping function back to the primal space.

Non-limiting examples of the ML model include supervised ML models such as nearest neighbor models, Naïve Bayes models, decision tree models, linear regression models, support vector machine (SVM) models, and neural network models, among others. In at least one variation, the ML model is a Gaussian Process regression model. Also, training of the ML model provides a prediction of an optimized material composition with respect to a predefined material property to within a desired value (i.e., less than or equal to a desired value) of a cost function.

In some variations, the convex function is a Softmax-affine function, the minimization function is a gradient descent function, the transform function is a re-plotting function and/or a duality transform function, among others, and the grouping function is a convex hull function. In at least one variation the duality transform function is a line-to-point and point-to-line duality transform function in which a line obeying the equation y=ax−b in an x,y primal space (two dimension material space) is duality transformed to a point with coordinates [a, b] in an a,b dual space, and a line obeying the equation b=xa−y in the a,b dual space is duality transformed to a point with coordinates [x, y] in the x,y primal space. In other variations, the ML system 10 is configured for material discovery in n-dimensional material space where n is an integer greater than 2. For example, in some variations the material space is a three dimension material space, the hyperplanes of the learned convex function are planes, the duality transformed hyperplanes of the learned convex function in the dual space are lines, the hyperplanes of the convex hull are planes, and the at least one duality transformed hyperplane of the convex hull in the primal space is at least two lines that intersect with each other.

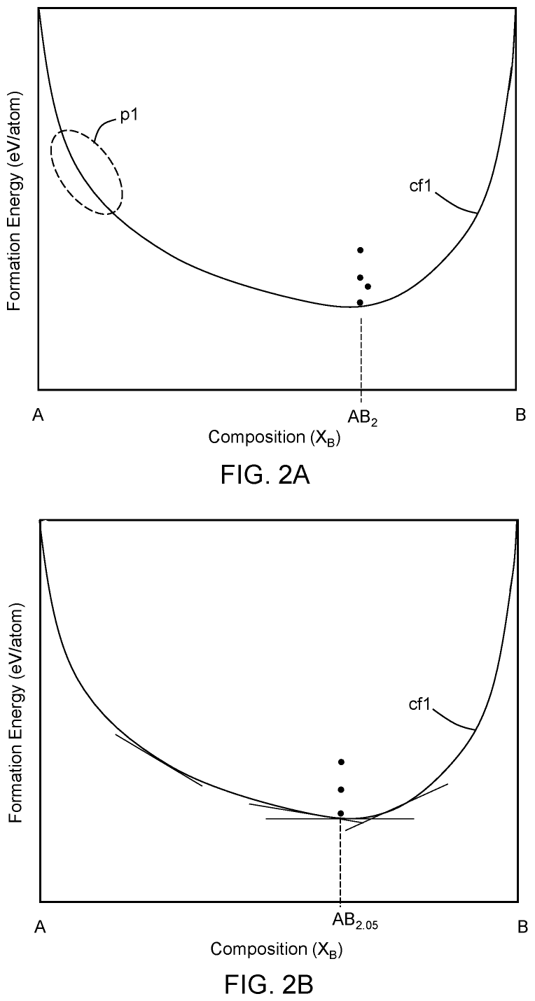

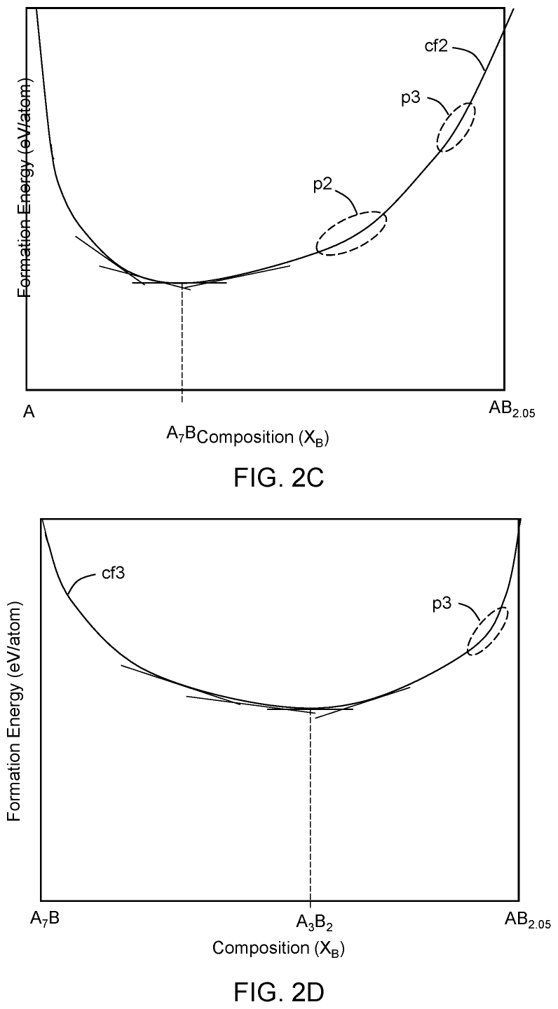

Referring to FIG. 2A a learned convex function ‘cf1’ for formation energy versus composition for a hypothetical A-B material system is shown. In some variations, a convex function is selected from the convex function module 125 and trained in order to provide the learned convex function cf1. And in at least one variation, the learned convex function cf1 is based, at least in part, on known experimental or calculated formation energy values for a given material composition as shown in FIG. 2A for the data points for the AB2 compound. Also, a protrusion ‘p1’ along the learned convex cf1 is shown in FIG. 2A is a protrusion ‘p1’.

Referring to FIG. 2B, a first learned minimum of the convex function cf1 is shown and the first learned minimum corresponds to a composition of AB2.os in the A-B system. It should be understood that the first learned minimum enhances material discovery by predicting an optimized material composition in the A-B system, e.g., a stable single-phase compound. In some variations of the present disclosure the first learned minimum reinforces known experimental or calculated data for a stable single-phase compound, i.e., the first learned minimum predicts that the known experimental or calculated data is in fact an accurate composition for a stable single-phase compound. In the alternative, or in addition to, the first learned minimum predicts a variation or difference in a material composition, compared to experimental or calculated data, to be studied.

Referring now to FIG. 2C, and regarding the protrusion p1 shown in FIG. 2A, a plot of the A-AB2.os subspace in FIG. 2A is shown with a learned convex function ‘cf2’. That is, the convex function f1 for the A-AB2.os subspace in FIG. 2A (first space) is re-plotted in FIG. 2C (second space), after changing reference energies, and the AB2.os composition is located on the right-most vertical axis of the plot shown in FIG. 2C. That is, the first learned minimum in the first space is an endpoint in the second space.

A second learned minimum of the learned convex function cf2 is also shown in FIG. 2C and corresponds to an ASB stable single-phase material. It should be understood that the second learned minimum of the learned convex function cf2 corresponds to the protrusion p1 that is present along the convex function cf1 (FIG. 2A). And as stated above with respect to the minimum of the first learned convex function cf1, the second learned minimum of the convex function cf2 can enhance material discovery by predicting a stable material composition in the A-B system, e.g., the stable single-phase compound ASB.

Referring to FIG. 2D, and regarding the protrusion ‘p2’ shown in FIG. 2C, a plot of the ASB-AB2.os subspace in FIG. 2C is shown with a learned convex function ‘cf3’. That is, the convex function cf2 for the ASB-AB2.os subspace in FIG. 2C (first space) is re-plotted in FIG. 2D (second space), after changing reference energies, such that the A7B2 composition is located on the left-most vertical axis of the plot shown in FIG. 2D. That is, the second learned minimum in the second space is an endpoint in the third space. In some variations the learned convex function cf3 is the same as the learned convex function cf2, i.e., a re-plotting transform function replots the convex function cf2 for the ASB-AB2.os subspace in FIG. 2C to the space shown in FIG. 2D.

A third learned minimum of the learned convex function cf3 is also shown in FIG. 2D and corresponds to an A3B2 material compound. It should be understood that the third learned minimum of the learned convex function cf3 corresponds to the protrusion p2 that is present along the convex function cf2 (FIG. 1C). And as stated above with respect to the first and second learned minimums of the learned convex functions cf1 and cf2, the third learned minimum of the convex function cf3 can enhance material discovery by predicting a stable material composition in the A-B system, e.g., the stable single-phase compound A₃B₂. It should also be understood that the same method can be used to find a fourth learned minimum of the protrusion ‘p3’ shown in FIG. 2C and predict another stable single-phase material.

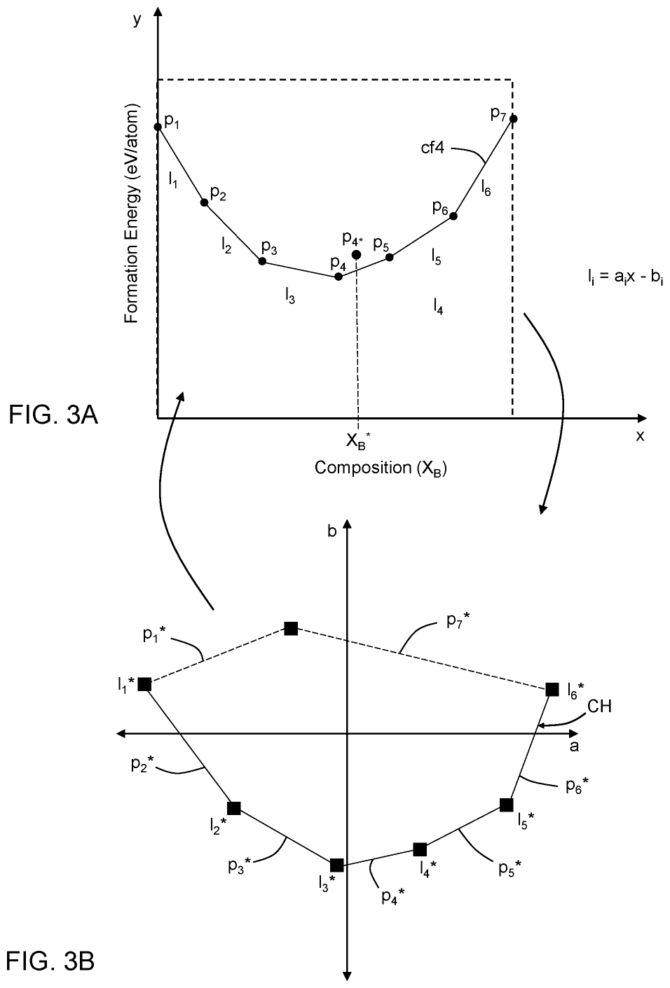

Referring now to FIGS. 3A and 3B, a method of predicting an optimized material composition using the ML system 10 according to another form of the present disclosure is shown. For example, FIG. 3A illustrates a learned convex function ‘cf4’ in FIG. 3A in the form of a plurality of hyperplanes I₁-I₆ with endpoints p1-p7 and FIG. 3B illustrates a dual space (not to scale) where duality transforms of the hyperplanes I₁-I₆ and endpoints p1-p7 have been plotted. In some variations, the learned convex function cf4 shown in FIG. 3A is a Softmax-affine function according the equation:

$${f}_{SMA} ( x ) = \frac{1}{α} log {\sum }_{k = 1}^{K} exp ( α ( {b}_{k} + {a}_{k}^{T} x ) )$$

where ƒSMA(x) is the property value for a given material property, x is material composition, and α, bₖ, and aₖ^{T} are fitting parameters. It should be understood that hyperplanes of the two dimensional surface or plane for the plot shown in FIG. 3A are one dimensional lines, i.e., hyperplanes I₁-I₆. Also, the duality transforms of the hyperplanes I₁-I₆ result in one dimension points I₁*-I₆* in the dual space shown in FIG. 3B. Similarly, the convex chain and learned convex hull ‘CH’ formed by lines p₁*-p₇* duality transform to points in the primal space shown in FIG. 3A. For example, the point p₄ shown in FIG. 3A is the duality transform of line p₄* in FIG. 3B and the point p₄* predicts X_{B}* as an optimized material composition. It should be understood that the “lower envelope” in FIG. 3A, i.e., the space below the learned convex function cf4, and the upper convex chain shown with dotted lines in FIG. 3B have no physical meaning, and thus the duality transform of lines p₂*-p₆* back to the primal space are the only transforms reviewed and analyzed for predicting an optimized material composition.

It should also be understood that the method of predicting an optimized material composition illustrated in FIGS. 3A and 3B can be used to predict optimized compositions for the protrusions p1-p3 in FIGS. 2A-2D. For example, the learned convex functions cf1-cf3 can be in the form of a plurality of hyperplanes, the plurality of hyperplanes can be duality transformed from the primal (first) space to a dual space, a convex hull of the transformed hyperplanes can be learned, and hyperplanes of the convex hull can be duality transformed back to the primal space such that one or more optimized material compositions are predicted.

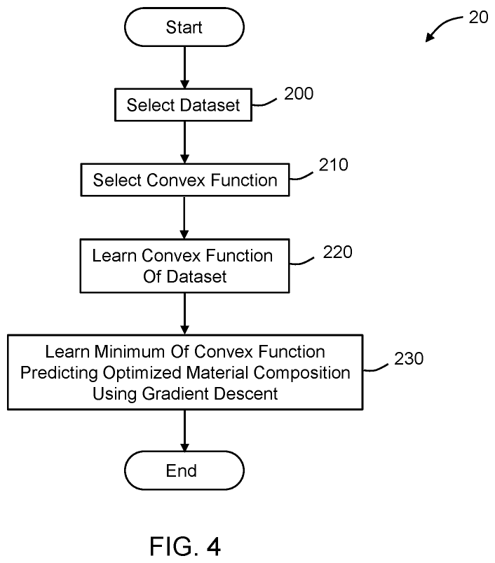

Referring now to FIG. 4, a flow chart for a ML method 20 for predicting an optimized material composition as illustrated in FIGS. 1A-1B is shown. The ML method 20 includes selecting a dataset at 200, selecting a convex function to approximate the dataset at 210, and training the convex function to fit the dataset at 220. Then the ML method 20 learns a minimum of the trained convex function using gradient descent at 230 such that an optimized material composition is predicted. In some variations, the dataset at 200 is a training dataset. And in such variations the method 20 includes learning a convex function of the training dataset at 220.

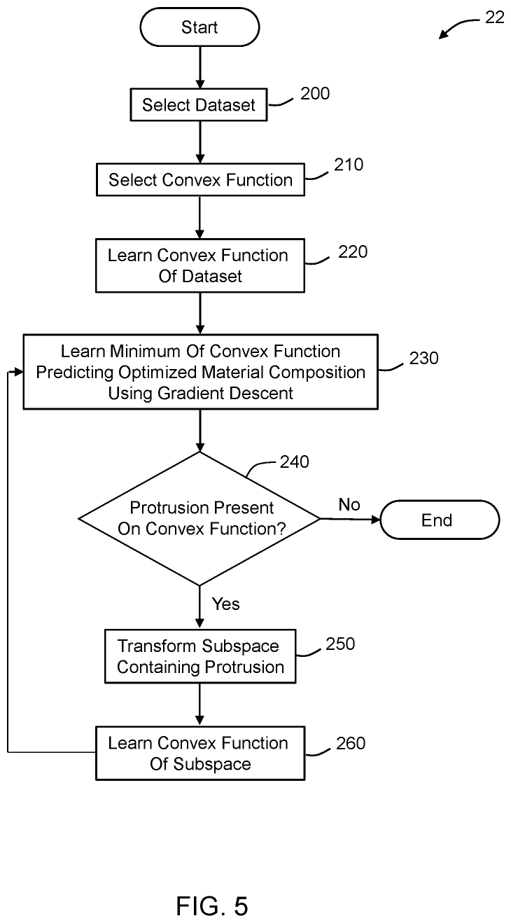

Referring now to FIG. 5, a flow chart for a ML method 22 for predicting optimized material compositions as illustrated in FIGS. 1A-1D is shown. The ML method 22 includes the same steps 200-230 as in method 20 and a minimum of a trained convex function using gradient descent is learned at 230 such that an optimized material composition is predicted. In addition, the method 22 includes determining whether or not a protrusion is present along the learned convex function at 240. If a protrusion is not present along the learned convex function, the method 20 ends. In the alternative, i.e., a protrusion is present along the learned convex function, the method 22 transforms a subspace of the learned convex function that includes the protrusion from a first space (e.g., FIG. 2A) to a second space (e.g., 2C) at 250, and learns a convex function of the subspace at 260. In some variations, the learned convex function at 260 is the same as the learned convex function at 220. The method 22 returns to 230 and learns a minimum of the trained convex function in the second space using gradient descent for the subspace at 230 such that another optimized material composition is predicted. The method repeats this cycle, i.e., 230-260-230, until no further protrusions are determined and then the method 22 ends.

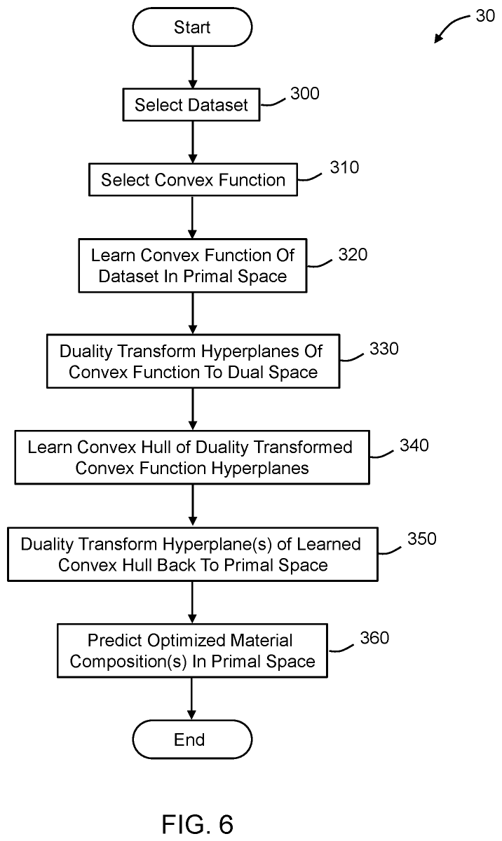

Referring to FIG. 6, a flow chart for still another ML method 30 for predicting an optimized material composition as illustrated in FIGS. 3A-3B is shown. The ML method 30 includes selecting a dataset at 300, selecting a convex function to approximate the dataset at 310 and training the convex function to approximate the dataset in a primal space at 320. The ML method 30 duality transforms hyperplanes of the trained convex function to a dual space at 330 and learns a convex hull of the duality transformed hyperplanes in the dual space at 340. At least one hyperplane of the convex hull is duality transformed back to the primal space at 350 and an optimized material composition is predicted in the primal space, based at least on the at least one duality transformed hyperplane of the convex hull.

The preceding description is merely illustrative in nature and is in no way intended to limit the disclosure, its application, or uses. Work of the presently named inventors, to the extent it may be described in the background section, as well as aspects of the description that may not otherwise qualify as prior art at the time of filing, are neither expressly nor impliedly admitted as prior art against the present technology.

As used herein, the phrase at least one of A, B, and C should be construed to mean a logical (A or B or C), using a non-exclusive logical “or.” It should be understood that the various steps within a method may be executed in different order without altering the principles of the present disclosure. Disclosure of ranges includes disclosure of all ranges and subdivided ranges within the entire range.

The headings (such as “Background” and “Summary”) and sub-headings used herein are intended only for general organization of topics within the present disclosure, and are not intended to limit the disclosure of the technology or any aspect thereof. The recitation of multiple variations or forms having stated features is not intended to exclude other variations or forms having additional features, or other variations or forms incorporating different combinations of the stated features.

As used herein the term “about” when related to numerical values herein refers to known commercial and/or experimental measurement variations or tolerances for the referenced quantity. In some variations, such known commercial and/or experimental measurement tolerances are +/−10% of the measured value, while in other variations such known commercial and/or experimental measurement tolerances are +/−5% of the measured value, while in still other variations such known commercial and/or experimental measurement tolerances are +/−2.5% of the measured value. And in at least one variation, such known commercial and/or experimental measurement tolerances are +/−1% of the measured value.

The flowcharts and block diagrams in the figures illustrate the architecture, functionality, and operation of possible implementations of systems, methods, and computer program products according to various embodiments. In this regard, a block in the flowcharts or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved.

The systems, components and/or processes described above can be realized in hardware or a combination of hardware and software and can be realized in a centralized fashion in one processing system or in a distributed fashion where different elements are spread across several interconnected processing systems. Any kind of processing system or another apparatus adapted for carrying out the methods described herein is suited. A typical combination of hardware and software can be a processing system with computer-usable program code that, when being loaded and executed, controls the processing system such that it carries out the methods described herein. The systems, components and/or processes also can be embedded in a computer-readable storage, such as a computer program product or other data programs storage device, readable by a machine, tangibly embodying a program of instructions executable by the machine to perform methods and processes described herein. These elements also can be embedded in an application product which comprises the features enabling the implementation of the methods described herein and, which when loaded in a processing system, is able to carry out these methods.

Furthermore, arrangements described herein may take the form of a computer program product embodied in one or more computer-readable media having computer-readable program code embodied, e.g., stored, thereon. Any combination of one or more computer-readable media may be utilized. The computer-readable medium may be a computer-readable signal medium or a computer-readable storage medium. The phrase “computer-readable storage medium” means a non-transitory storage medium. A computer-readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer-readable storage medium would include the following: a portable computer diskette, a hard disk drive (HDD), a solid-state drive (SSD), a ROM, an EPROM or flash memory, a portable compact disc read-only memory (CD-ROM), a digital versatile disc (DVD), an optical storage device, a magnetic storage device, or any suitable combination of the foregoing. In the context of this document, a computer-readable storage medium may be any tangible medium that can contain, or store a program for use by or in connection with an instruction execution system, apparatus, or device.

Generally, modules as used herein include routines, programs, objects, components, data structures, and so on that perform particular tasks or implement particular data types. In further aspects, a memory generally stores the noted modules. The memory associated with a module may be a buffer or cache embedded within a processor, a RAM, a ROM, a flash memory, or another suitable electronic storage medium. In still further aspects, a module as envisioned by the present disclosure is implemented as an ASIC, a hardware component of a system on a chip (SoC), as a programmable logic array (PLA), or as another suitable hardware component that is embedded with a defined configuration set (e.g., instructions) for performing the disclosed functions.

Program code embodied on a computer-readable medium may be transmitted using any appropriate medium, including but not limited to wireless, wireline, optical fiber, cable, radio frequency (RF), etc., or any suitable combination of the foregoing. Computer program code for carrying out operations for aspects of the present arrangements may be written in any combination of one or more programming languages, including an object-oriented programming language such as Java™, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer, or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

As used herein, the terms “comprise” and “include” and their variants are intended to be non-limiting, such that recitation of items in succession or a list is not to the exclusion of other like items that may also be useful in the devices and methods of this technology. Similarly, the terms “can” and “may” and their variants are intended to be non-limiting, such that recitation that a form or variation can or may comprise certain elements or features does not exclude other forms or variations of the present technology that do not contain those elements or features.

The broad teachings of the present disclosure can be implemented in a variety of forms. Therefore, while this disclosure includes particular examples, the true scope of the disclosure should not be so limited since other modifications will become apparent to the skilled practitioner upon a study of the specification and the following claims. Reference herein to one variation, or various variations means that a particular feature, structure, or characteristic described in connection with a form or variation or particular system is included in at least one variation or form. The appearances of the phrase “in one variation” (or variations thereof) are not necessarily referring to the same variation or form. It should be also understood that the various method steps discussed herein do not have to be carried out in the same order as depicted, and not each method step is required in each variation or form.

The foregoing description of the forms and variations has been provided for purposes of illustration and description. It is not intended to be exhaustive or to limit the disclosure. Individual elements or features of a particular form or variation are generally not limited to that particular form or variation, but, where applicable, are interchangeable and can be used in a selected form or variation, even if not specifically shown or described. The same may also be varied in many ways. Such variations should not be regarded as a departure from the disclosure, and all such modifications are intended to be included within the scope of the disclosure.

What is claimed is:

1. A system comprising:
a processor; and
a memory communicably coupled to the processor and storing machine-readable instructions that, when executed by the processor, cause the processor to:
select a dataset representing at least a portion of a material space;
train a machine learning model to learn a convex function approximating the dataset in a primal space;
duality transform hyperplanes of the learned convex function from the primal space to a dual space;
learn a convex hull of the duality transformed convex function hyperplanes in the dual space;
duality transform at least one hyperplane of the learned convex hull back to the primal space; and
predict, based on the at least one duality transformed hyperplane of the learned convex hull, at least one optimized material composition within the material space.

2. The system according to claim 1 further comprising a convex hull module with instructions that when executed by the processor cause the processor to select the convex function to approximate the dataset in the primal space.

3. The system according to claim 2, wherein the selected convex function is a Softmax-affine function.

4. The system according to claim 3, wherein the Softmax-affine function is:
$${f}_{SMA} ( x ) = \frac{1}{α} log {\sum }_{k = 1}^{K} exp ( α ( {b}_{k} + {a}_{k}^{T} x ) )$$
where ƒSMA(x) is formation energy, x is material composition, and α, bₖ, and aₖ^{T} are fitting parameters.

5. The system according to claim 1, wherein the material space is a two dimension material space, the hyperplanes of the learned convex function are lines, the duality transformed hyperplanes of the learned convex function in the dual space are points, the at least one hyperplane of the convex hull is a line, and the at least one duality transformed hyperplane of the convex hull in the primal space is at least one point.

6. The system according to claim 1, wherein the dataset comprises formation energy versus composition data and the at least one optimized material composition is a stable single-phase material composition.

7. The system according to claim 1, wherein the learned convex function includes a plurality of protrusions.

8. The system according to claim 7, wherein each of the plurality of protrusions is approximated by a convex function and a set of hyperplanes such that a plurality of sets of hyperplanes are duality transformed to the dual space.

9. The system according to claim 8, wherein the convex function is a Softmax-affine function.

10. The system according to claim 9, wherein the machine learning module includes instructions that when executed by the processor cause the processor during one or more iterations to learn a convex hull for each the plurality of sets of hyperplanes.

11. The system according to claim 10, wherein at least one hyperplane for each of the convex hulls is duality transformed back to the primal space such that a plurality of optimized material compositions are predicted by the machine learning module.

12. The system according to claim 1 further comprising a transform module with instructions that when executed by the processor cause the processor to duality transform the hyperplanes of the learned convex function from the primal space to the dual space.

13. The system according to claim 12, wherein the transform module includes instructions that when executed by the processor cause the processor to duality transform the at least one hyperplane of the learned convex hull back to the primal space.

14. The system according to claim 1, wherein the material space is a three dimension material space, the hyperplanes of the learned convex function are planes, the duality transformed hyperplanes of the learned convex function in the dual space are lines, the at least one hyperplane of the convex hull is a plurality of planes, and the at least one duality transformed hyperplane of the convex hull in the primal space is at least two lines that intersect with each other.

15. A system comprising:
a processor; and
a memory communicably coupled to the processor and storing machine-readable instructions that, when executed by the processor, cause the processor to:
select a dataset representing at least a portion of a material space;
train a machine learning model to learn a convex function approximating the dataset in a first space;
learn a first minimum of learned convex function in the first space;
transform a subspace of the learned convex function from the first space to a second space, the first learned minimum in the first space being an endpoint in the second space;
learn a second minimum of the subspace of the learned convex function in the second space; and
predict, based at least in part on the first learned minimum and the second learned minimum a first optimized material composition and a second optimized material composition different than the first optimized material composition within the material space.

16. The system according to claim 15, wherein the memory communicably coupled to the processor and storing the machine-readable instructions that, when executed by the processor, further cause the processor to:
transform a subspace of the learned convex function from the second space to a third space, the second learned minimum in the second space being an endpoint in the third space;
learn a third minimum of the subspace of the learned convex function in the third space; and
predict, based at least in part on the third learned minimum, a third optimized material composition within the material space.

17. The system according to claim 16, wherein the first optimized material composition, the second optimized material composition, and the third optimized material composition are a stable single-phase material compositions.

18. A method comprising:
selecting a dataset from a candidate dataset, the dataset representing at least a portion of a material space;
training a machine learning model to learn a convex function approximating the dataset in a primal space;
duality transforming hyperplanes of the learned convex function from the primal space to a dual space;
learning a convex hull of the duality transformed convex function hyperplanes in the dual space;
duality transforming at least one hyperplane of the learned convex hull back to the primal space; and
predicting, based on the at least one duality transformed hyperplane of the learned convex hull, at least one stable material composition within the material space.

19. The method according to claim 18, wherein convex function is:
$${f}_{SMA} ( x ) = \frac{1}{α} log {\sum }_{k = 1}^{K} exp ( α ( {b}_{k} + {a}_{k}^{T} x ) )$$
where ƒSMA(x) is formation energy, x is material composition, and α, bₖ, and aₖ^{T} are fitting parameters.

20. The method according to claim 19, wherein the predicted at least one stable material composition within the material space is a stable single-phase material composition.
